(19) United States
(12) Patent Application Publication
(10) Pub. No.: US 2025/0293108 A1
(43) Pub. Date: Sep. 18, 2025

(54) SEMICONDUCTOR PACKAGE AND MANUFACTURING METHOD FOR THE SAME

(71) Applicant: Samsung Electronics Co., Ltd., Suwon-si (KR)

(72) Inventor: SEUNGDUK BAEK, Suwon-si (KR)

(21) Appl. No.: 18/828,625

(22) Filed: Sep. 9, 2024

(30) Foreign Application Priority Data
Mar. 12, 2024 (KR) 10-2024-0034507

(51) Int. Cl. H01L 23/31; H01L 21/56; H01L 23/00; H01L 25/00; H01L 25/18; H10B 80/00

(52) U.S. Cl. CPC H01L 23/3135; H01L 21/56; H01L 24/08; H01L 24/09; H01L 25/18; H01L 25/50; H01L 24/80; H01L 2224/08146; H01L 2224/09181; H01L 2224/80895; H01L 2224/80896; H10B 80/00

(57) ABSTRACT

A semiconductor package which includes a plurality of first semiconductor chips that are stacked, a molding material surrounding side surfaces of the plurality of first semiconductor chips, and a moisture permeation prevention film continuously positioned between the side surfaces of each of the plurality of first semiconductor chips and the molding material. Each of the plurality of first semiconductor chips comprises a first bonding pad and a second bonding pad positioned at opposite surfaces from each other, and wherein the second bonding pad of one of the plurality of first semiconductor chips is in contact with a first bonding pad of another one of the plurality of first semiconductor chips.

### CROSS-REFERENCE TO RELATED APPLICATION

This application claims priority under 35 U.S.C. § 119 to and the benefit of Korean Patent Application No. 10-2024-0034507 filed in the Korean Intellectual Property Office on Mar. 12, 2024, the entire content of which is incorporated herein by reference.

### BACKGROUND OF THE INVENTION

Aspects of the present disclosure relate to a semiconductor package and a method of manufacturing the same.

With the increasing demand for down-sized electronic devices, various technologies are being studied to satisfy characteristics such as light, thin, short, compact, excellent reliability, high performance, and large capacity of semiconductor packages. Among these technologies, a hybrid bonding technology that directly bonds the bonding pads of each of the upper semiconductor chip and the lower semiconductor chip without using a separate solder bump is known. Hybrid bonding technology enables fine pitch implementation and has the advantage of excellent heat dissipation characteristics.

For example, hybrid bonding may be performed by surface-treating the insulating layers positioned around the bonding pads of the upper semiconductor chip and the lower semiconductor chip, and then compressing the upper semiconductor chip and the lower semiconductor chip to induce bonding between the surface-treated insulating layers, followed by bonding the bonding pads of the upper semiconductor chip and the lower semiconductor chip through annealing.

### SUMMARY

In one aspect, the present disclosure provides to prevent metal migration of bonding pads that may occur at the interface of hybrid bonded semiconductor chips and electrical short circuits caused by the metal migration.

The present disclosure provides, as an embodiment, a semiconductor package which includes a plurality of first semiconductor chips stacked in a vertical direction; a molding material surrounding side surfaces of the plurality of first semiconductor chips; and a moisture permeation prevention film continuously positioned between the side surfaces of each of the plurality of first semiconductor chips and the molding material, wherein each of the plurality of first semiconductor chips comprises a first bonding pad and a second bonding pad positioned at opposite surfaces from each other, and wherein the second bonding pad of one of the plurality of first semiconductor chips is in contact with a first bonding pad of another one of the plurality of first semiconductor chips.

In another embodiment, the present disclosure provides a semiconductor package which includes a first semiconductor chip including a first bonding pad, a first through via, and a second bonding pad electrically connected to the first through via; a plurality of second semiconductor chips stacked on the first semiconductor chip and including a third bonding pad, a second through via, and a fourth bonding pad each electrically connected to the second through via; a molding material positioned on the first semiconductor chip and surrounding side surfaces of the plurality of second semiconductor chips; and a moisture permeation prevention film continuously positioned between an upper surface of the first semiconductor chip and the molding material, and between the side surfaces of each of the plurality of second semiconductor chips and the molding material, wherein a third bonding pad of a second semiconductor chip positioned at the lowermost side of the plurality of second semiconductor chips is in contact with the second bonding pad, wherein a fourth bonding pad of one of the plurality of second semiconductor chips is in contact with the third bonding pad of another one of the plurality of second semiconductor chips, and wherein a thickness of the moisture permeation prevention film in a direction perpendicular to the upper surface of the first semiconductor chip between the upper surface of the first semiconductor chip and the molding material and a thickness of the moisture permeation prevention film in a direction perpendicular to the side surface of the second semiconductor chips between the side surfaces of each of the plurality of second semiconductor chips and the molding material is 5 μm or less, respectively.

As another embodiment, the present disclosure provides a semiconductor package manufacturing method including; placing a first semiconductor wafer on a carrier substrate; bonding a plurality of second semiconductor chips including a first bonding pad and a second bonding pad positioned at opposite surfaces from each other on the first semiconductor wafer; forming a moisture permeation prevention film on an exposed upper surface of the first semiconductor wafer, a side of the plurality of the second semiconductor chips, and an upper surface of the second semiconductor chip positioned at an uppermost side among the plurality of second semiconductor chips; molding the plurality of second semiconductor chips and the moisture permeation prevention film with a molding material; removing the above carrier substrate; and dicing the first semiconductor wafer and separating the first semiconductor wafer into first semiconductor chips, wherein, in the bonding the plurality of second semiconductor chips, a second bonding pad of one of the plurality of second semiconductor chips is in contact with a first bonding pad of another one of the plurality of second semiconductor chips,

According to an aspect of the present disclosure, it is possible to prevent metal migration of a bonding pad that may occur at an interface of hybrid bonded semiconductor chips and an electrical short circuit caused by the metal migration.

### BRIEF DESCRIPTION OF THE DRAWINGS

FIG. 1 is a cross-sectional view of a semiconductor package according to an embodiment of the present disclosure.

FIG. 2 is a cross-sectional view of a semiconductor package according to a comparative example.

FIGS. 3A, 3B, and 3C are diagrams for explaining a problem that may occur in the semiconductor package of FIG. 2.

FIG. 4 is a cross-sectional view of a semiconductor package according to an embodiment of the present disclosure.

FIG. 5 is a cross-sectional view of a semiconductor package according to an embodiment of the present disclosure.

FIG. 6 is a cross-sectional view of a semiconductor package according to an embodiment of the present disclosure.

FIG. 7 is a cross-sectional view of a semiconductor package according to an embodiment of the present disclosure.

FIGS. 8-14 are manufacturing process diagrams of the semiconductor package of FIG. 1.

FIGS. 15-22 are manufacturing process diagrams of the semiconductor package of FIG. 4.

### DETAILED DESCRIPTION

Hereinafter, with reference to the accompanying drawing, several embodiments of the present disclosure will be described in detail so that a person of an ordinary skill can easily practice it in the technical field to which the present disclosure belongs. The present disclosure may be implemented in several different forms and is not limited to the embodiments described herein.

In order to clearly explain the present disclosure, parts that do not have a relationship with the explanation are omitted, and identical or similar component is assigned the same reference numerals throughout the specification.

In addition, the size and thickness of each component shown in the drawing are arbitrarily shown for better understanding and ease of description, so the present disclosure is not necessarily limited to what is shown. In the drawings, the thickness of layers, films, panels, regions, etc., are exaggerated for clarity. And in the drawings, for the convenience of explanation, the thickness of some layers and regions is exaggerated.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact. From a similar perspective, it may include not only being “physically connected” but also being “electrically connected”. In addition, when a part “includes” a component throughout the specification, unless explicitly described to the contrary, this means other components may be further included, rather than excluding other components unless otherwise stated.

In addition, when an element such as a layer, film, region, or substrate is referred to as being “above” or “on” another element, this may include not only the case where the other element is “directly on” but also the case where there is other element in the middle. In contrast, when an element is referred to as being “directly on” another element, there are no intervening elements present. In addition, being “above” or “on” a reference part means being positioned above or below the reference part and does not necessarily mean being positioned “above” or “on” it in the opposite direction of gravity.

In addition, when a part “includes” a component throughout the specification, this means other components may be further included, rather than excluding other components unless otherwise stated.

In addition, throughout the specification, when it comes to “on a plane,” it means when the target part is viewed from above, and when it comes to “cross-section,” it means when the cross-section of the target part is vertically cut from the side.

In addition, throughout the specification, the order of first, second, etc. is used to distinguish a component from another component that is the same or similar and is not necessarily used to refer to a specific component. Therefore, a configuration referred to as the first component in a specific part of this specification may be referred to as the second component in another part of this specification.

In addition, throughout the specification, a singular reference to a component may include a plural reference to a plurality of components unless otherwise stated. For example, the “insulation layer” may be used to mean not only one insulation layer but also a plurality of insulation layers, such as two, three, or more.

In addition, throughout the specification, the upper and lower surfaces are described based on the upper and lower surfaces on the drawing, respectively. Therefore, the upper and lower surfaces referred to in the specification should be understood with reference to the drawings.

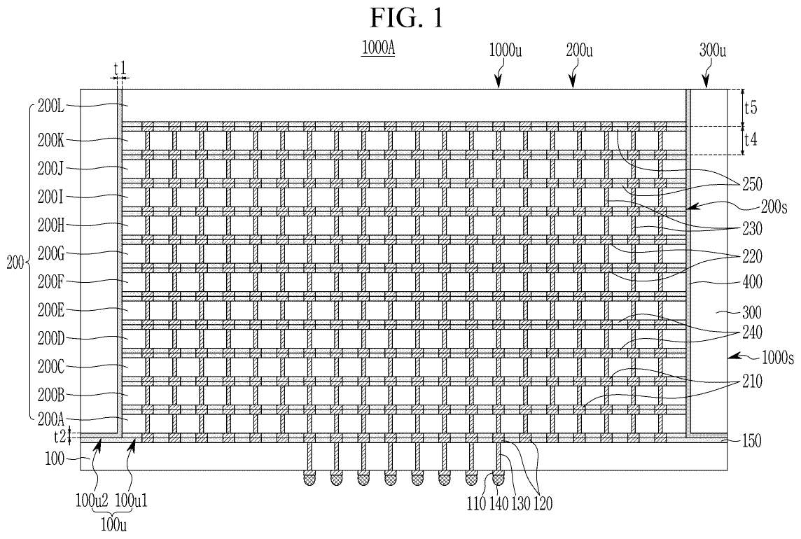

FIG. 1 is a cross-sectional view of a semiconductor package according to an embodiment of the present disclosure.

Referring to the drawings, a semiconductor package 1000A includes a first semiconductor chip 100, a plurality of second semiconductor chips 200 stacked on the first semiconductor chip 100, a molding material 300 positioned on the first semiconductor chip 100 to surround the side surfaces 200s of the plurality of second semiconductor chips 200, and a moisture permeation prevention film 400 positioned continuously between the molding material 300 and the side surfaces 200s of each of the plurality of second semiconductor chips 200.

The first semiconductor chip 100 may include a first bonding pad 110, a second bonding pad 120, a first through via 130, and a conductive bump 140. The first bonding pad 110, the second bonding pad, the first through via 130, and the conductive bump 140 may be electrically connected to each other.

The first bonding pad 110 is positioned on the lower surface of the first semiconductor chip 100. The lower surface of the first semiconductor chip 100 may be an active surface adjacent to a plurality of individual devices formed through front end of line (FEOL) and back end of line (BEOL) processes on a semiconductor substrate, an internal circuit, and the like.

The first through via 130 penetrates at least a portion of the first semiconductor chip 100 in the thickness direction. Although the first through via 130 is shown to be in contact with the first bonding pad 110 and the second bonding pad 120, it may be indirectly connected to the first bonding pad 110 or the second bonding pad 120. As an example, but not limited thereto, the first through via 130 may be indirectly connected to the first bonding pad 110 through an internal circuit.

The depth at which the first through via 130 penetrates the first semiconductor chip 100 may vary according to design and manufacturing processes. For example, depending on the selective application of via-first, via-middle, and via-last processes, the depth and area of the first semiconductor chip 100 through which the first through via 130 passes may vary.

The second bonding pad 120 is positioned on the upper surface of the first semiconductor chip 100. The upper surface of the first semiconductor chip 100 may be an inactive surface adjacent to the semiconductor substrate. The second bonding pad 120 may be a pad for electrically connecting the first through via 130 to the second semiconductor chip 200A positioned at the lowermost side among the plurality of second semiconductor chips 200 stacked in a vertical direction on the first semiconductor chip 100.

The conductive bump 140 may electrically connect the semiconductor package 1000A to other components such as a main substrate. The conductive bump 140 may be, for example, a solder ball.

The first semiconductor chip 100 may be hybrid-bonded to the second semiconductor chip 200A positioned at the lowermost side among a plurality of second semiconductor chips 200. Therefore, the second bonding pad 120 of the first semiconductor chip 100 may be electrically connected to the third bonding pad 210 of the second semiconductor chip 200A positioned at the lowermost side among the plurality of second semiconductor chips 200.

The first semiconductor chip 100 may further include a first bonding insulation layer 150 surrounding the second bonding pad 120. During hybrid bonding, the first bonding insulation layer 150 may be bonded by contacting the second bonding insulation layer 240 of the second semiconductor chip 200A positioned at the lowermost side among the plurality of second semiconductor chips 200. As the material of the first bonding insulation layer 150, an insulation material may be used, for example, an inorganic material such as silicon oxide, an organic material such as benzocyclobutene (BCB), etc. may be used.

The upper surface 100u of the first semiconductor chip 100 may be divided in two regions, a first upper surface region 100u1 and a second upper surface region 100u2. The second upper surface region 100u2 may surround the first upper surface region 100u1. A plurality of second semiconductor chips 200 may be position on the first semiconductor chip 100 in the first upper surface region 100u1. A molding material 300 may be positioned on the first semiconductor chip 100 in the second upper surface region 100u2. In addition, as described later, the moisture permeation prevention film 400, positioned continuously between the molding material 300 and the side surfaces 200s of each of the plurality of second semiconductor chips 200, may further extend so as to be positioned on the second upper surface region 100u2 between the molding material 300 and of the first semiconductor chip 100 . . . . As such, the second upper surface region 100u2 of the upper surface 100u of the first semiconductor chip 100, which does not overlap the second semiconductor chips 200 in the vertical direction, may be covered with the moisture permeation prevention film 400. Within the second upper surface region 100u2, a bottom surface of the moisture permeation prevention film 400 may contact a top surface of the first bonding insulating layer 150.

Although not illustrated, the first bonding insulation layer 150 may only be disposed on the first upper surface region 100u1 of the first semiconductor chip 100 and may not be disposed on the second upper surface region 100u2 of the first semiconductor chip 100. As such, the moisture permeation prevention film 400, positioned continuously between the molding material 300 and the side surfaces 200s of each of the plurality of second semiconductor chips 200, may further extend so as to be positioned on the second upper surface region 100u2 between the molding material 300 and the first semiconductor chip 100. A bottom surface of the moisture permeation prevention film 400 disposed on the second upper surface region 100u2, may be coplanar with a bottom surface of the first bonding insulation layer 150 disposed on the first upper surface region 100u1. In the present specification, the term “coplanar” means a case in which certain components are positioned at exactly the same level as well as a case in which they have a minute level difference due to an error in a manufacturing process.

The first semiconductor chip 100 may be a logic chip for configuring a high bandwidth memory package. In the technical field to which the present disclosure pertains, the first semiconductor chip 100 may be referred to as a buffer chip, a base chip, or the like.

A plurality of second semiconductor chips 200 may be stacked on the first semiconductor chip 100 to be in contact with each other. The number of the plurality of second semiconductor chips 200 is not limited to the number illustrated in the drawing and may also be greater or less than the number illustrated in the drawing.

Each of a plurality of second semiconductor chips 200 may include a third bonding pad 210, a second through via 230, and a fourth bonding pad 220.

The third bonding pad 210 is positioned on a lower surface of each of the second semiconductor chips 200. The lower surface of the second semiconductor chips 200 may be an active surface adjacent to a plurality of individual devices, internal circuits, and the like formed through FEOL and BEOL processes on the semiconductor substrate.

The second through via 230 may penetrate at least a portion of each of the second semiconductor chips 200 in a thickness direction and may be electrically connected to the third bonding pad 210 or the fourth bonding pad 220. Although the second through via 230 is shown to be connected in contact with the third bonding pad 210 and the fourth bonding pad 220, it may be indirectly connected to the third bonding pad 210 or the fourth bonding pad 220. As an example, but not limited thereto, the second through via 230 may be indirectly connected to the third bonding pad 210 through an internal circuit.

The depth at which the second through via 230 penetrates each of the second semiconductor chips 200 may vary according to design and manufacturing processes. For example, depending on the selective application of via-first, via-middle, and via-last processes, the depth and area of each of the second semiconductor chips 200 through which the second through via 230 passes may vary.

The fourth bonding pad 220 is positioned on an upper surface of each of the second semiconductor chips 200. The upper surface of each of the second semiconductor chips 200 may be an inactive surface adjacent to the semiconductor substrate. The fourth bonding pad 220 may be a pad for electrically connecting the second through via 230 to another second semiconductor chip.

As described above, the second semiconductor chip 200A positioned at the lowermost side among the plurality of second semiconductor chips 200 may be hybrid-bonded to the first semiconductor chip 100. Therefore, the third bonding pad 210 of the second semiconductor chip 200A positioned at the lowermost side among the plurality of second semiconductor chips 200 may be electrically connected to the second bonding pad 120 of the first semiconductor chip 100.

Also, a plurality of second semiconductor chips 200 may be hybrid-bonded to each other. Accordingly, the fourth bonding pad 220 of one of the plurality of second semiconductor chips 200 may contact the third bonding pad 210 of another one of the plurality of second semiconductor chips 200. For example, the fourth bonding pad 220 of the second semiconductor chip 200A may be in contact with the third bonding pad 210 of the second semiconductor chip 200B, and the fourth bonding pad 220 of the second semiconductor chip 200K may be in contact with the third bonding pad 210 of the second semiconductor chip 200L.

In an embodiment, the thickness t5 of the second semiconductor chip 200L positioned at the uppermost side among a plurality of second semiconductor chips 200 may be thicker than the thickness t4 of the remaining second semiconductor chips 200A, 200B, 200C, 200D, 200E, 200F, 200G, 200H, 200I, 200J, and 200K. The second semiconductor chip 200L positioned at the uppermost side among the plurality of second semiconductor chips 200 may not include the second through via 230 or the third bonding pad 210 as a component for electrical connection with another semiconductor chip positioned on the upper surface thereof. Since the second semiconductor chip 200L has a relatively thick thickness, heat dissipation characteristics of the semiconductor package 1000A may be improved.

Each of a plurality of second semiconductor chips 200 may further include a second bonding insulation layer 240 surrounding the third bonding pad 210 and a third bonding insulation layer 250 surrounding the fourth bonding pad 220. During hybrid bonding, the third bonding insulation layer 250 of one of the plurality of second semiconductor chips 200 may be bonded in contact with the second bonding insulation layer 240 of another one of the plurality of second semiconductor chips 200. For example, the third bonding insulation layer 250 of the second semiconductor chip 200A may be bonded in contact with the second bonding insulation layer 240 of the second semiconductor chip 200B, and the third bonding insulation layer 250 of the second semiconductor chip 200K may be bonded in contact with the second bonding insulation layer 240 of the second semiconductor chip 200L. In addition, the second bonding insulation layer 240 of the second semiconductor chip 200A positioned at the lowermost side among the plurality of second semiconductor chips 200 may be bonded by contacting the first bonding insulation layer 150 of the first semiconductor chip 100. An insulation material may be used as a material for each of the second bonding insulation layer 240 and the third bonding insulation layer 250, for example, an inorganic material such as silicon oxide, an organic material such as benzocyclobutene (BCB), etc. may be used.

The upper surface 200u of the second semiconductor chip 200L positioned at the uppermost side among the plurality of second semiconductor chips 200 may be coplanar with the upper surface 300u of the molding material 300. During manufacturing, molding material 300 may be removed from the upper surface 200u of the second semiconductor chip 200L by grinding (e.g., etching) the molding material 300, and thus the upper surface 200u of the second semiconductor chip 200L positioned at the uppermost side may coplanar with the upper surface 300u of the molding material 300. Since the second semiconductor chip 200L is exposed (i.e., not covered by the molding material 300), heat dissipation characteristics of the semiconductor package 1000A may be maximized. In addition, the second semiconductor chip 200L may constitute the upper surface 1000u of the semiconductor package together with the moisture permeation prevention film 400 and the molding material 300. For example, the upper surface 200u of the second semiconductor chip 200L, the upper surface of the moisture permeation prevention film 400, and the upper surface 300u of the molding material 300 may be coplanar with each other.

Each of a plurality of second semiconductor chips 200 may be a high bandwidth memory chip for configuring a high bandwidth memory (HBM) package. In the technical field to which the present disclosure belongs, a plurality of second semiconductor chips 200 may be referred to as a core chip, a secondary chip, and the like.

The molding material 300 may surround the side surfaces 200s of the plurality of second semiconductor chips 200 and may cover the moisture permeation prevention film 400 positioned between the molding material 300 and the plurality of second semiconductor chips 200. The molding material 300 may be formed of an epoxy mold compound (EMC), a thermosetting resin such as an epoxy resin, or a thermoplastic resin such as polyimide.

The moisture permeation prevention film 400 is continuously positioned between the side surface 200s of each of the plurality of second semiconductor chips 200 and the molding material 300. Here, being positioned ‘continuously’ means having boundaries with each other or being positioned without any interrupted areas. In addition, the moisture permeation prevention film 400 may be extended to be positioned between the second upper surface region 100u2 of the first semiconductor chip 100 and the molding material 300. Through a structure in which the moisture permeation prevention film 400 extends to be positioned between the second upper surface region 100u2 of the first semiconductor chip 100 and the molding material 300, it is possible to efficiently block moisture from penetrating into the interface between the first semiconductor chip 100 and the second semiconductor chip 200A. The moisture permeation prevention film 400 may prevent metal migration of the bonding pad caused by moisture penetration into the interface between adjacent second semiconductor chips among the plurality of second semiconductor chips 200 and may avoid an electrical short circuit caused by the metal migration.

However, for heat dissipation characteristics, the moisture permeation prevention film 400 may not exist on all of the plurality of second semiconductor chips 200. For example, although not illustrated, the moisture permeation prevention film 400 may not exist on the second semiconductor chip 200L positioned at the uppermost side. In such a configuration, the second semiconductor chip 200L may constitute the upper surface 1000u of the semiconductor package together with the molding material 300. For example, the upper surface 200u of the second semiconductor chip 200L and the upper surface 300u of the molding material 300 may be coplanar with each other.

As illustrated in FIG. 1, the moisture permeation prevention film 400 may be exposed to the side surface 1000s of the semiconductor package 1000A together with the first semiconductor chip 100 and the molding material 300. As will be described later in the description of the manufacturing process of the semiconductor package, when dicing the first semiconductor chip 100 and the molding material 300 in a wafer state, as the moisture permeation prevention film 400 is diced together, the moisture permeation prevention film 400 may be exposed to the side surface 1000s of the semiconductor package 1000A. In addition, the moisture permeation prevention film 400 may constitute a side surface 1000s of the semiconductor package together with the first semiconductor chip 100 and the molding material 300.

As the material of the moisture permeation prevention film 400, an inorganic material, an organic material, or the like having low moisture permeability may be used. The moisture permeation prevention film 400 may include at least one of silicon nitride (SixNy), silicon oxynitride (SiON), carbon-containing silicon oxide (SiOC), titanium dioxide (TiO2), aluminum oxide (Al2O3), tin oxide (SnOx), polyethylene terephthalate (PET), polypropylene (PP), polyethylene (PE), and polymethyl methacrylate (PMMA). In Formula SixNy of the silicon nitride, the range of x may be 0<x<4, the range of y may be 0<y<4, and for example, the silicon nitride may be Si3N4. Also, in the formula SnOx of the tin oxide, the range of the x value may be 0<x<2, for example, the tin oxide may be SnO or SnO2.

The thicknesses t1 and t2 of the moisture permeation prevention film 400 may be less than or equal to 5 μm. The thickness of the moisture permeation prevention film 400 means a thickness in a direction perpendicular to the surface covered by the moisture permeation prevention film 400 of the component covered by the moisture permeation prevention film 400. For example, the thickness t1 of the moisture permeation prevention film 400 between the side surface 200s of each of the plurality of second semiconductor chips 200 and the molding material 300 means a thickness in a direction perpendicular to the side surfaces 200s of the second semiconductor chips 200 (e.g., a horizontal direction). In addition, the thickness t2 of the moisture permeation prevention film 400 between the second upper surface region 100u2 of the first semiconductor chip 100 and the molding material 300 means the thickness in a direction perpendicular to the second upper surface region 100u2 of the first semiconductor chip 100 (e.g., a vertical direction). When the thicknesses t1 and t2 of the moisture permeation prevention film 400 exceed 5 μm, the process time for forming the moisture permeation prevention film 400 is lengthened, and warpage characteristics may be disadvantageous. In addition, when the moisture permeation prevention film 400 includes an inorganic material, problems such as cracking, bending, and peeling of the moisture permeation prevention film 400 may occur. Therefore, it may be preferable to form the thickness of the moisture permeation prevention film 400 to be 5 μm or less.

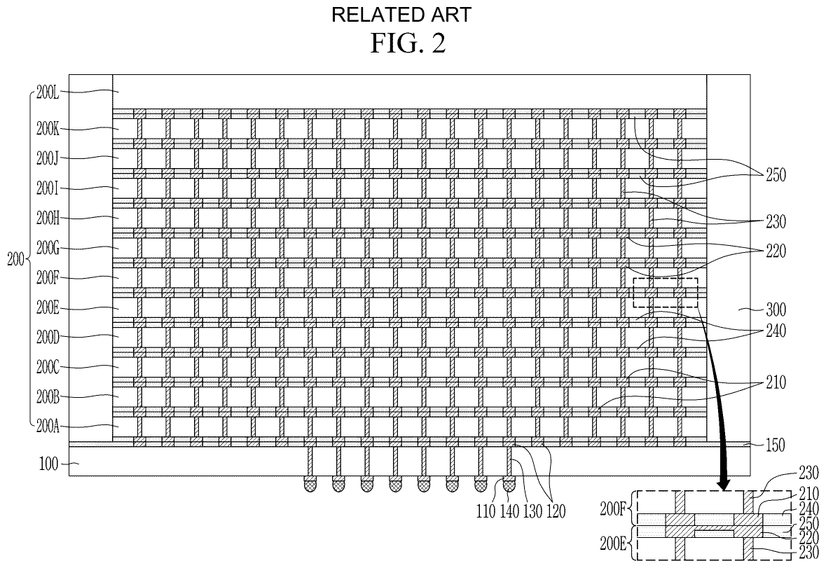

FIG. 2 is a cross-sectional view of a semiconductor package according to a comparative example.

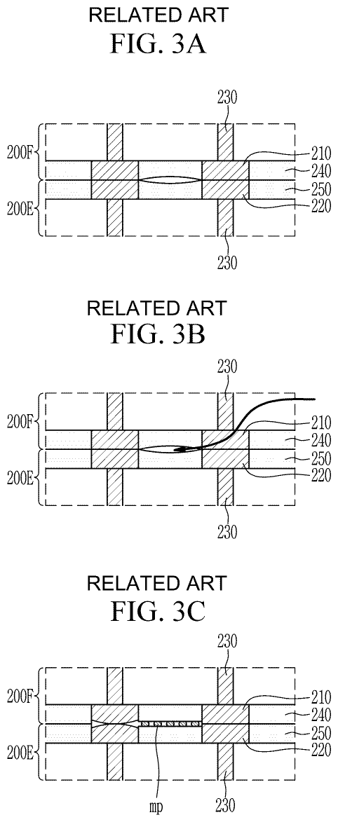

FIGS. 3A, 3B, and 3C are diagrams for explaining a problem that may occur in the semiconductor package of FIG. 2.

Referring to FIGS. 2 and 3A-3C, when the semiconductor package does not include a moisture permeation prevention film, moisture may penetrate the molding material 300 from an external environment and flow into the interface between the first semiconductor chip 100 and the second semiconductor chip 200A or between adjacent second semiconductor chips 200. When there is a void or unbonded area at the interface between adjacent semiconductor chips, metal migration of the bonding pad through this area and electrical short circuit caused by the metal migration may occur.

For example, when the second semiconductor chips 200 are hybrid-bonded, a void or unbonded region may occur between the third bonding insulation layer 250 of the second semiconductor chip 200E and the second bonding insulation layer 240 of the second semiconductor chip 200F, and moisture may penetrate the void or unbonded region. (See FIGS. 3A and 3B). After that, when heat is applied to the semiconductor package due to high-temperature reliability evaluation, metal migration may occur in which metal particles (mp) of the bonding pads 210 and 220 move to the void or unbonded area. This metal migration may cause an electrical short between adjacent bonding pads, such as power pads and ground pads.

On the other hand, according to the present disclosure, since the semiconductor package 1000A includes the moisture permeation prevention film 400, metal migration of the bonding pad and short circuit caused by the metal migration may be prevented.

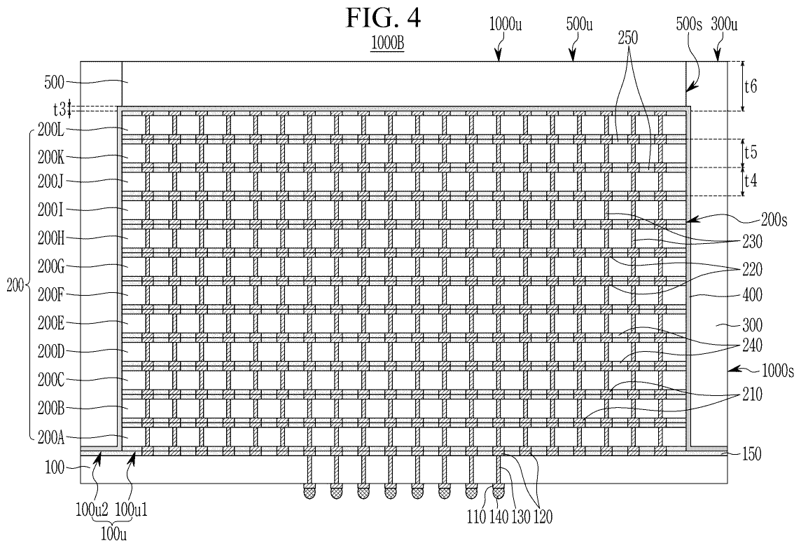

FIG. 4 is a cross-sectional view of a semiconductor package according to an embodiment of the present disclosure.

Compared with the semiconductor package 1000A, the semiconductor package 1000B further includes a third semiconductor chip 500 positioned on a plurality of second semiconductor chips 200, and the molding material 300 further surrounds the side surface 500s of the third semiconductor chip 500.

The thickness t6 of the third semiconductor chip 500 may be thicker than the thicknesses t4 and t5 of each of the plurality of second semiconductor chips 200. Since the third semiconductor chip 500 has a relatively thick thickness, heat dissipation characteristics of the semiconductor package 1000B may be improved. As the third semiconductor chip 500 serves to improve heat dissipation characteristics, the thickness t5 of the second semiconductor chip 200L positioned at the uppermost side among the plurality of second semiconductor chips 200 may be equal to the thickness t4 of the remaining second semiconductor chips 200A, 200B, 200C, 200D, 200E, 200F, 200G, 200H, 200I, 200J, 200K. In addition, the second semiconductor chip 200L may include a second through via 230 and a fourth bonding pad 220, similar to the remaining second semiconductor chips 200A, 200B, 200C, 200D, 200E, 200F, 200G, 200H, 200I, 200J, and 200K.

The upper surface 500u of the third semiconductor chip 500 may be exposed (i.e., not covered by the molding material 300). During manufacturing, molding material 300 disposed on the upper surface 500u of the third semiconductor chip 500 may be removed by grinding the molding material 300, and thus the upper surface 500u of the third semiconductor chip 500 may be coplanar with the upper surface 300u of the molding material 300. Since the third semiconductor chip 500 is exposed (i.e., not covered by the molding material 300), heat dissipation characteristics of the semiconductor package 1000B may be maximized. In addition, the third semiconductor chip 500 may constitute an upper surface 1000u of the semiconductor package together with the molding material 300.

The third semiconductor chip 500 may be a dummy chip. The dummy chip may be a silicon substrate, a glass substrate, or a metal plate.

The width of the third semiconductor chip 500 may be substantially the same as the width of each of the plurality of second semiconductor chips 200, but is not limited thereto.

In the semiconductor package 1000B, the moisture permeation prevention film 400 may extend to be positioned between the plurality of second semiconductor chips 200 and the third semiconductor chip 500. For example, the moisture permeation prevention film 400 may extend to be positioned between uppermost side among the plurality of second semiconductor chips 200 (e.g., the upper surface of the second semiconductor chip 200L) and the third semiconductor chip 500. The moisture permeation prevention film 400 may contact the upper surface of the second semiconductor chip 200L and the bottom surface of the third semiconductor chip 500. In some embodiments, an adhesive member may be positioned between the moisture permeation prevention film 400 and the third semiconductor chip 500. However, the moisture permeation prevention film 400 may not be disposed between the side surface 500s of the third semiconductor chip 500 and the molding material 300.

A thickness t3 of the moisture permeation prevention film 400 between a plurality of second semiconductor chips 200 and the third semiconductor chip 500 may be less than or equal to 5 μm. The thickness t3 of the moisture permeation prevention film 400 between a plurality of second semiconductor chips 200 and the third semiconductor chip 500 means a thickness in a direction perpendicular to the upper surface of the second semiconductor chips 200 and the lower surface of the third semiconductor chip 500.

In addition, the above-described contents in the description of the semiconductor package 1000A may be equally applied to the description of the semiconductor package 1000B unless particularly contradictory.

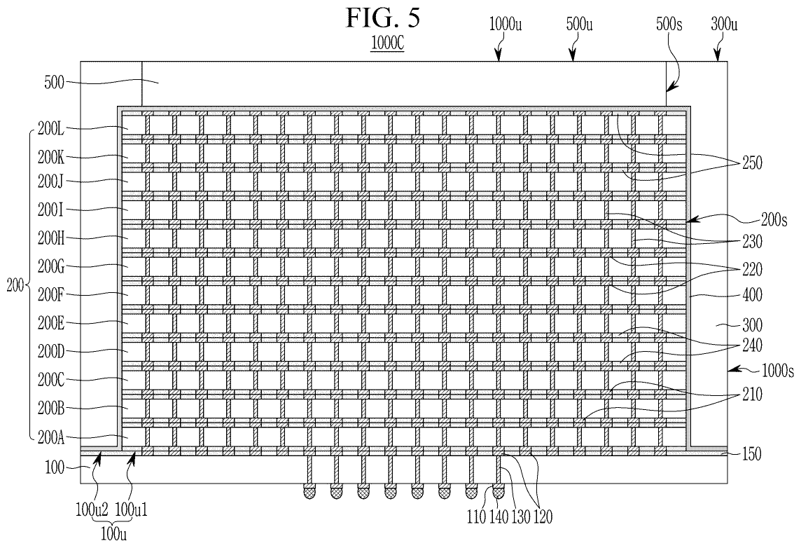

FIG. 5 is a cross-sectional view of a semiconductor package according to an embodiment of the present disclosure.

Referring to the drawing, in the semiconductor package 1000C, compared to the semiconductor package 1000B, the width of the third semiconductor chip 500 may be narrower than the width of each of the plurality of second semiconductor chips 200. In the present specification, the width means the width in the cross section.

In addition, the above-described description of the semiconductor packages 1000A and 1000B may be equally applied to the description of the semiconductor packages 1000C unless particularly contradictory.

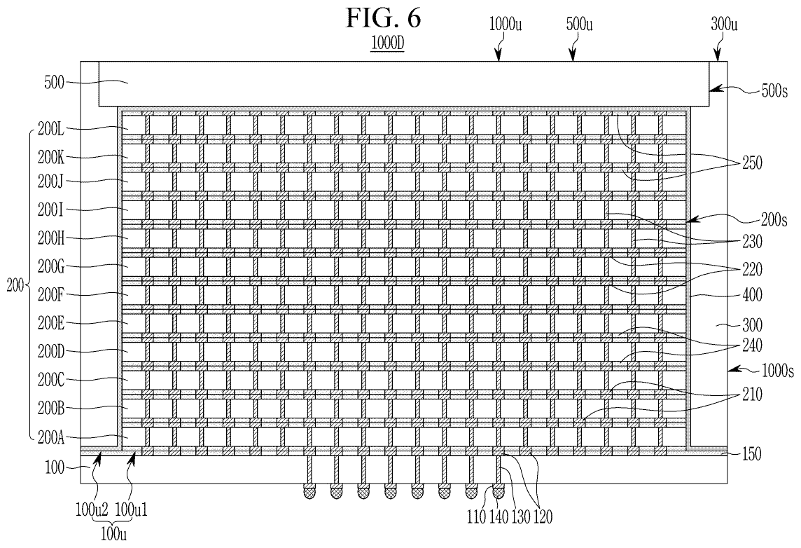

FIG. 6 is a cross-sectional view of a semiconductor package according to an embodiment of the present disclosure.

Referring to the drawing, in the semiconductor package 1000D, compared to the semiconductor package 1000B, the width of the third semiconductor chip 500 may be wider than that of each of the plurality of second semiconductor chips 200. In addition, the above-described description of the semiconductor packages 1000A and 1000B may be equally applied to the description of the semiconductor packages 1000D unless particularly contradictory.

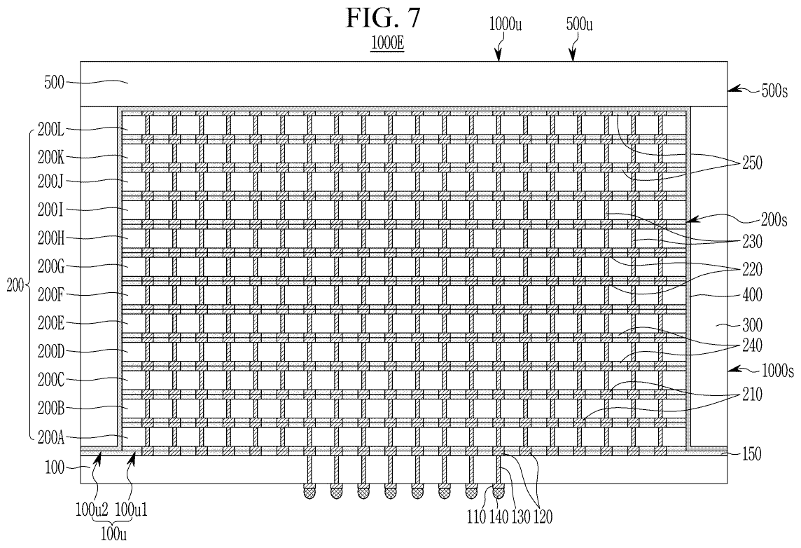

FIG. 7 is a cross-sectional view of a semiconductor package according to an embodiment of the present disclosure.

Referring to the diagram, in the semiconductor package 100E, compared to the semiconductor package 1000B, the width of the third semiconductor chip 500 may be wider than each of the plurality of second semiconductor chips 200 and may be exposed to the side surfaces 1000s of the semiconductor package 1000E. For example, the side surfaces of the third semiconductor chip 500 may not be covered by the molding material 300. The third semiconductor chip 500 may constitute a side surface 1000s of the semiconductor package together with the moisture permeation prevention film 400, the first semiconductor chip 100, and the molding material 300. For example, the side surfaces of the third semiconductor chip 500, the moisture permeation prevention film 400, the first semiconductor chip 100, and the molding material 300 may be coplanar with each other.

In addition, the above-described description of the semiconductor packages 1000A and 1000B may be equally applied to the description of the semiconductor packages 1000E unless particularly contradictory.

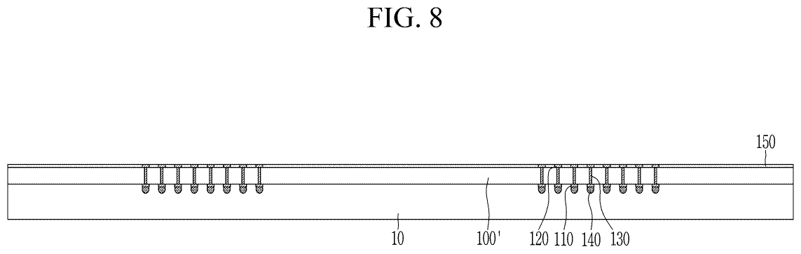

FIGS. 8 to 14 are manufacturing process diagrams of the semiconductor package of FIG. 1.

A method of manufacturing a semiconductor package may include a step of disposing the first semiconductor wafer 100′ on a carrier substrate 10, a step of bonding a plurality of second semiconductor chips 200 on the first semiconductor wafer 100′, a step of forming a moisture permeation prevention film 400 on an exposed upper surface 100u′ of the first semiconductor wafer 100′, a side surface 200s of the plurality of second semiconductor chips 200, and an upper surface 200u of the second semiconductor chip 200L positioned at the uppermost side among the plurality of second semiconductor chips 200, a step of molding a plurality of second semiconductor chips 200 and a moisture permeation prevention film 400 with a molding material 300, a step of removing the carrier substrate 10, and a step of dicing the first semiconductor wafer 100′ to separate into first semiconductor chips 100.

Referring to FIG. 8, a first semiconductor wafer 100′ is first disposed on the carrier substrate 10. The first semiconductor wafer 100′ has a structure before being diced into a plurality of first semiconductor chips 100, and may include first bonding pads 110, first through vias 130, second bonding pads 120, conductive bumps 140, and a first bonding insulation layer 150 formed in regions corresponding to the first semiconductor chips 100. The first semiconductor wafer 100′ may be arranged such that the first bonding pad 110 and the conductive bump 140 face the carrier substrate 10.

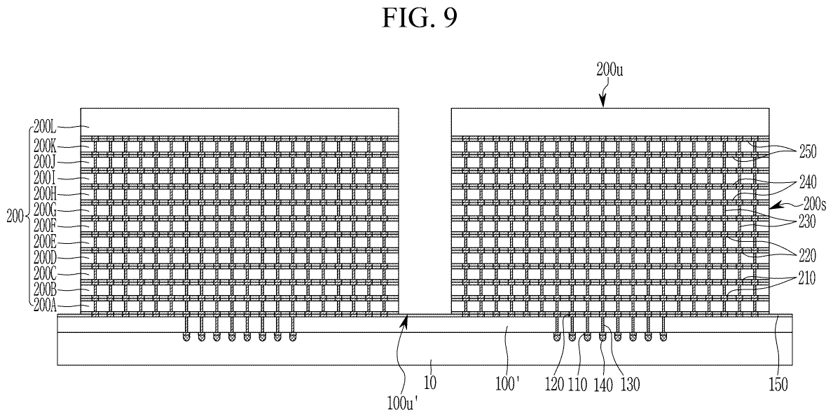

Next, referring to FIG. 9, a plurality of second semiconductor chips 200 are bonded on the first semiconductor wafer 100′.

Each of the plurality of second semiconductor chips 200 may include a third bonding pad 210, a second through via 230, and a fourth bonding pad 220, and may be hybrid-bonded to each other. Thus, the fourth bonding pad 220 of one of the plurality of second semiconductor chips 200 may be bonded in contact with the third bonding pad 210 of another one among the plurality of second semiconductor chips 200. Additionally, the third bonding insulation layer 250 of one of the plurality of second semiconductor chips 200 may be bonded in contact with the second bonding insulation layer 240 of another one among the plurality of second semiconductor chips 200.

The second semiconductor chip 200A positioned at the lowermost side among the plurality of second semiconductor chips 200 may be hybrid-bonded to the first semiconductor wafer 100′. Therefore, the third bonding pad 210 of the second semiconductor chip 200A positioned at the lowermost side among the plurality of second semiconductor chips 200 may be bonded by contacting the second bonding pad 120 of the first semiconductor wafer 100′. In addition, the second bonding insulation layer 240 of the second semiconductor chip 200A positioned at the lowermost side among the plurality of second semiconductor chips 200 may be bonded by contacting the first bonding insulation layer 150 of the first semiconductor chip 100.

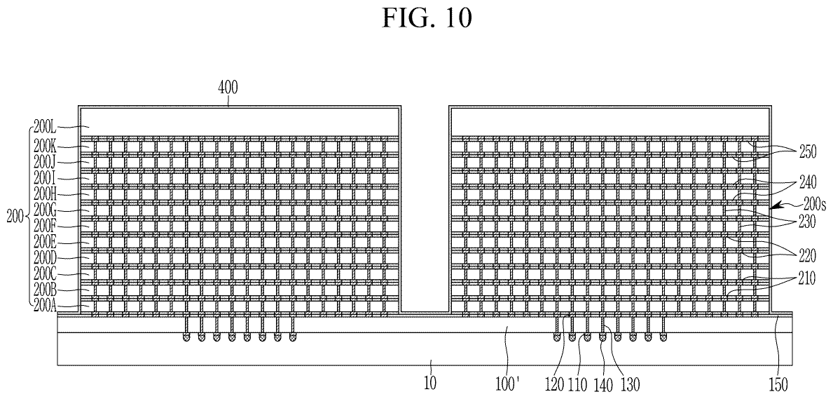

Next, referring to FIG. 10, a moisture permeation prevention film 400 is formed. The moisture permeation prevention film 400 may be formed by coating inorganic materials such as silicon nitride (SixNy), silicon oxynitride (SiON), carbon-containing silicon oxide (SiOC), titanium dioxide (TiO2), aluminum oxide (Al2O3), tin oxide (SnOx), or organic materials such as polyethylene terephthalate (PET), polypropylene (PP), polyethylene (PE), polymethyl methacrylate (PMMA), etc. with chemical vapor deposition (CVD), spray coating, or spin coating.

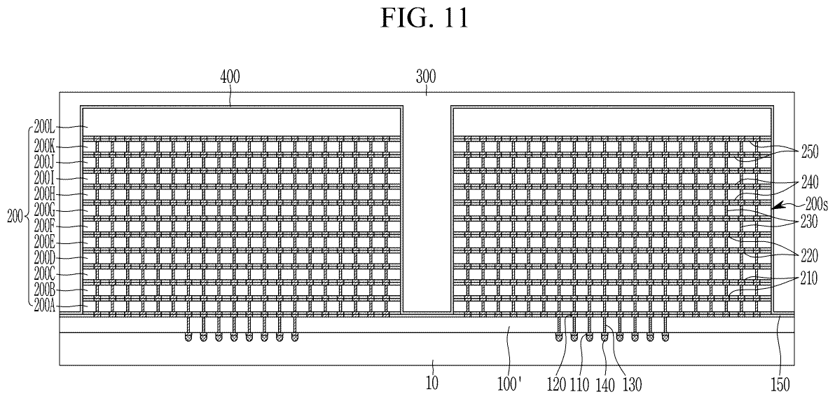

Next, referring to FIG. 11, a plurality of second semiconductor chips 200 and the moisture permeation prevention film 400 are molded with a molding material 300. The molding may be performed by compression molding, transfer molding, or the like, and the moisture permeation prevention film 400 may be covered with a molding material 300.

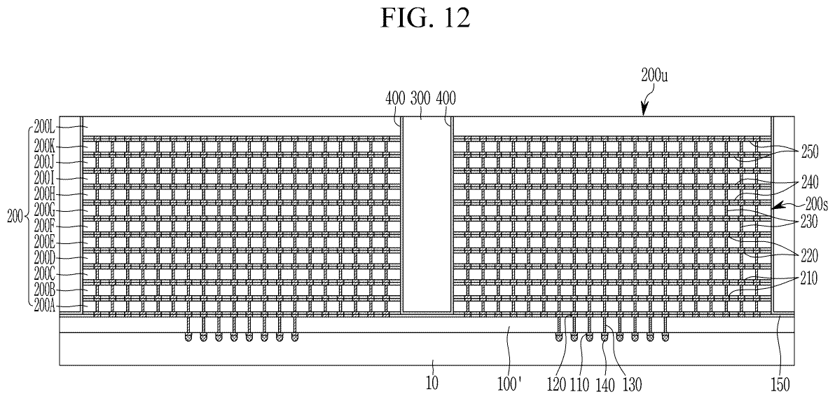

Next, referring to FIG. 12, the molding material 300 and the moisture permeation prevention film 400 are ground (e.g., etched) to expose the upper surface 200u of the second semiconductor chip 200L, which is positioned at the uppermost side among the plurality of second semiconductor chips 200. In this case, a part of the second semiconductor chip 200L may be ground together with the molding material 300 and the moisture permeation prevention film 400, and the ground surface may constitute the upper surface 200u of the second semiconductor chip 200L in the semiconductor package 1000A. In the present specification, the same reference numerals are used for the upper surface 200u of the second semiconductor chip 200L before grinding and the upper surface 200u of the second semiconductor chip 200L after grinding. In addition, by the grinding process, the second semiconductor chip 200L, the moisture permeation prevention film 400, and the molding material 300 may constitute the upper surface 1000u of the semiconductor package 1000A.

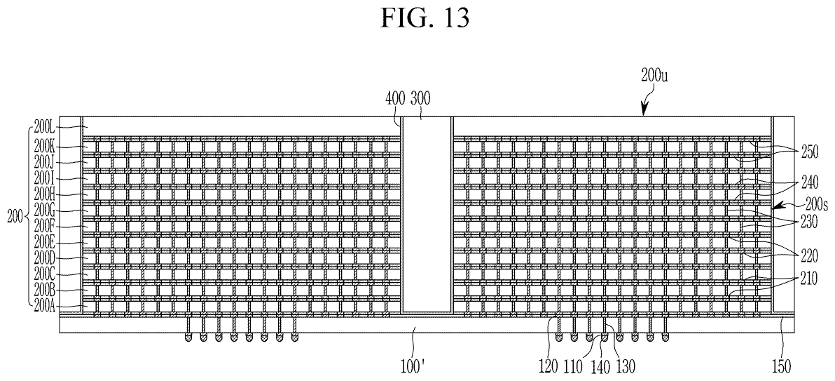

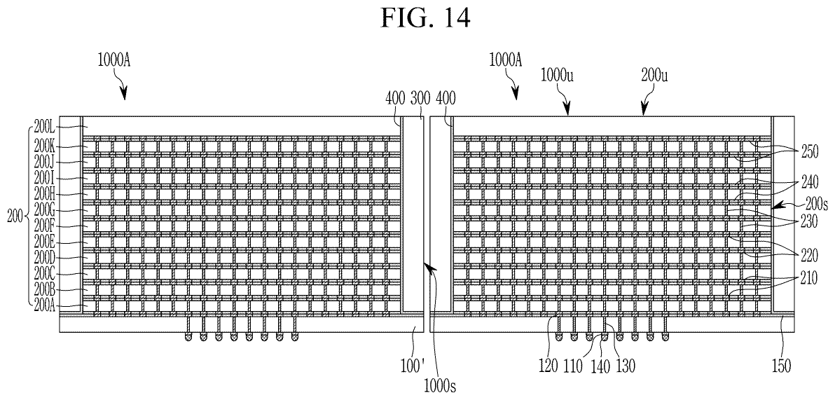

Next, referring to FIGS. 13 and 14, a semiconductor package 1000A may be manufactured by removing the carrier substrate 10 and dicing the first semiconductor wafer 100′ to separate into first semiconductor chips 100. When dicing the first semiconductor wafer 100′, the molding material 300 and the moisture permeation prevention film 400 positioned in the dicing area may be diced together with the first semiconductor wafer 100′. By the dicing process, the first semiconductor chip 100, the moisture permeation prevention film 400, and the molding material 300 may form the side surface 1000s of the semiconductor package 1000A.

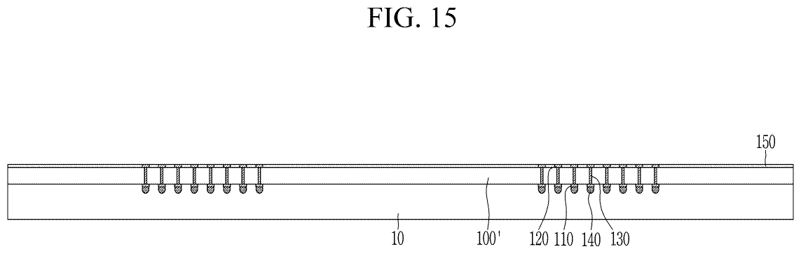

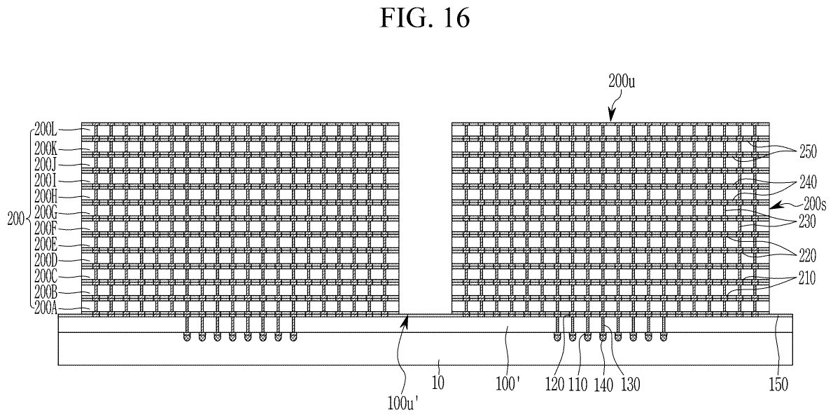

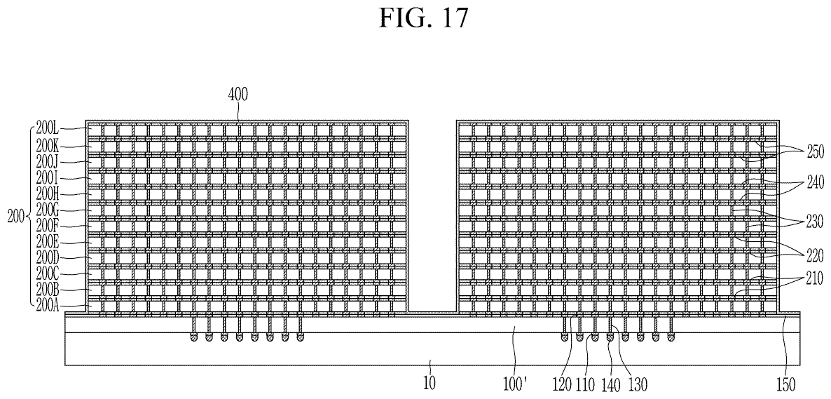

FIGS. 15 to 22 are manufacturing process diagrams of the semiconductor package of FIG. 4.

In an embodiment, compared to the manufacturing method shown in FIGS. 8 to 14, the method of manufacturing a semiconductor package further includes a step of disposing the third semiconductor chip 500 on the plurality of second semiconductor chips 200 and the moisture permeation prevention film 400, and a step of grinding the molding material 300 to expose the upper surface 500u of the third semiconductor chip 500. In addition, in the molding step with the molding material 300, the third semiconductor chip 500 is molded with the molding material 300 along with the plurality of second semiconductor chips 200 and the moisture permeation prevention film 400.

Referring to FIGS. 15 to 17, a first semiconductor wafer 100′ is first disposed on the carrier substrate 10, and a plurality of second semiconductor chips 200 are bonded on the first semiconductor wafer 100′, and then a moisture permeation prevention film 400 is formed.

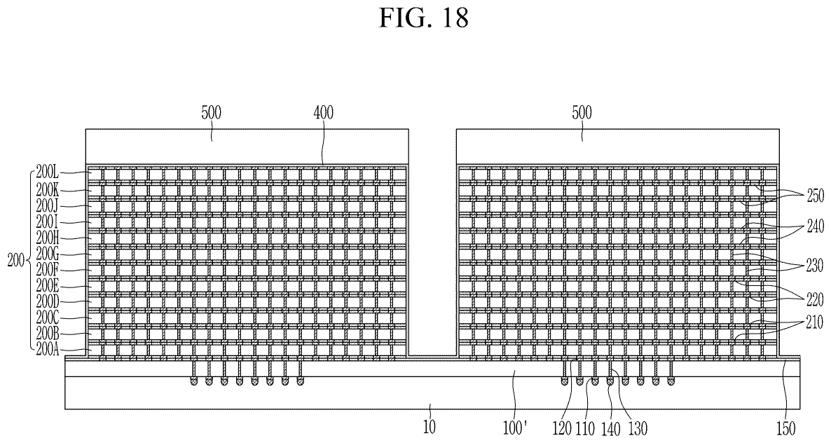

Next, referring to FIG. 18, a third semiconductor chip 500 is disposed on a plurality of second semiconductor chips 200 and the moisture permeation prevention film 400. If necessary, the third semiconductor chip 500 may be attached to the moisture permeation prevention film 400 through an adhesive member.

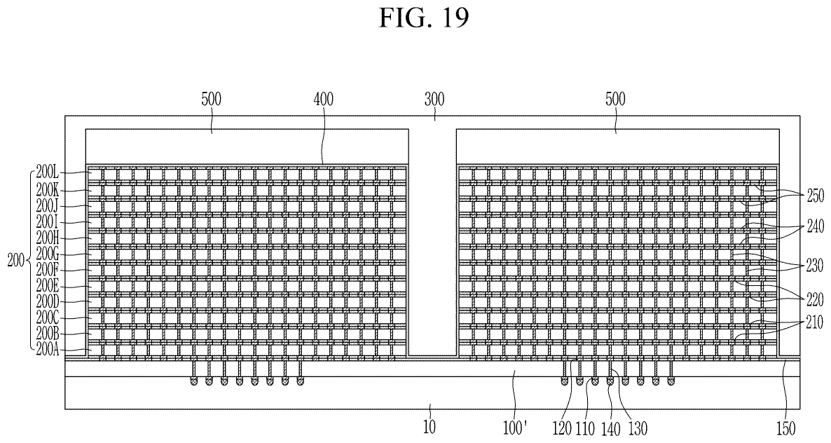

Next, referring to FIG. 19, a plurality of second semiconductor chips 200, a moisture permeation prevention film 400, and a third semiconductor chip 500 are molded with a molding material 300. In this case, an upper surface of the third semiconductor chip 500 may be covered with a molding material 300 together with the moisture permeation prevention film 400.

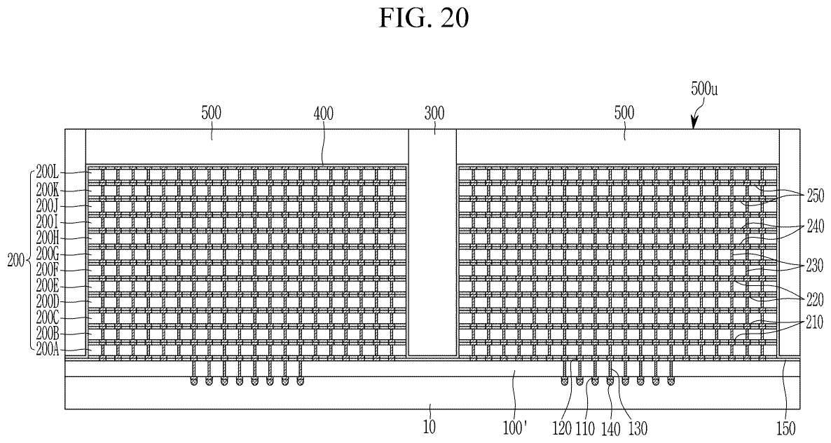

Next, referring to FIG. 20, the molding material 300 is ground to expose the upper surface 500u of the third semiconductor chip 500. In this case, a part of the third semiconductor chip 500 may be ground together with the molding material 300, and the ground surface may constitute the upper surface 500u of the third semiconductor chip 500 in the semiconductor package 1000B. In addition, by the grinding process, the third semiconductor chip 500 and the molding material 300 may constitute the upper surface 1000u of the semiconductor package 1000B.

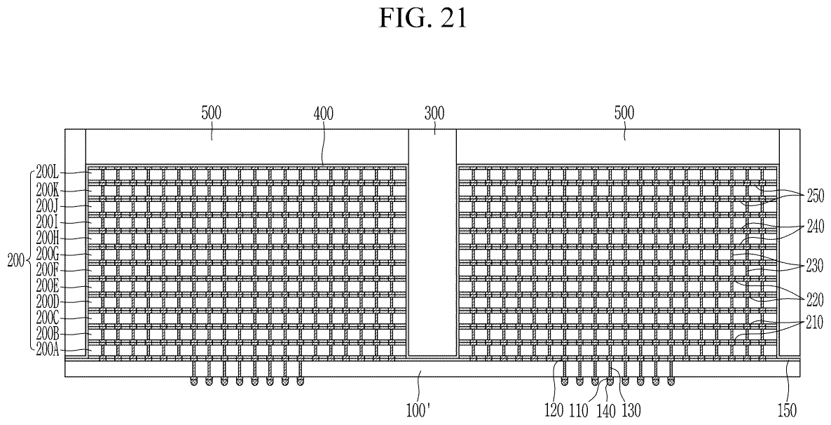

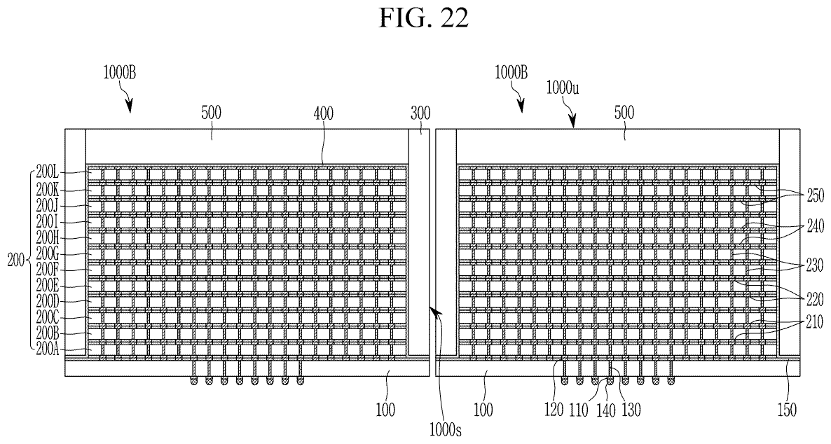

Next, referring to FIGS. 21 and 22, a semiconductor package 1000B may be manufactured by removing the carrier substrate 10 and dicing the first semiconductor wafer 100′ to separate into the first semiconductor chips 100.

Unless it contradicts the description of the manufacturing method illustrated in FIGS. 15 to 22, the same description may be applied to the description of the manufacturing method illustrated in FIGS. 8 to 14.

Although the embodiments of the disclosure have been described in detail above, the scope of the present disclosure is not limited to the scope of the present disclosure, but various modifications and improvements of the person of an order skill in the art using the basic concept of the present disclosure defined in the following claim range also belong to the scope of the present disclosure.

What is claimed is:

1. A semiconductor package comprising:
a plurality of first semiconductor chips stacked in a vertical direction;
a molding material surrounding side surfaces of the plurality of first semiconductor chips; and
a moisture permeation prevention film continuously positioned between the side surfaces of each of the plurality of first semiconductor chips and the molding material,
wherein each of the plurality of first semiconductor chips comprises a first bonding pad and a second bonding pad positioned at opposite surfaces from each other, and
wherein the second bonding pad of one of the plurality of first semiconductor chips is in contact with the first bonding pad of another one of the plurality of first semiconductor chips.

2. The semiconductor package of claim 1,
further comprising a second semiconductor chip,
wherein the plurality of first semiconductor chips and the molding material are positioned on the second semiconductor chip, and
wherein the moisture permeation prevention film extends between an upper surface of the second semiconductor chip and the molding material.

3. The semiconductor package of claim 2, wherein:
the moisture permeation prevention film extends to a side surface of the semiconductor package and is coplanar with the molding material.

4. The semiconductor package of claim 2, wherein:
a region of the upper surface of the second semiconductor chip covered by the moisture permeation prevention film and a region of the upper surface of the second semiconductor chip overlapping the first semiconductor chips are coplanar.

5. The semiconductor package of claim 1, wherein:
each of the plurality of first semiconductor chips includes a first bonding insulation layer and a second bonding insulation layer positioned at opposite surfaces from each other, and
wherein the second bonding insulation layer of one of the plurality of first semiconductor chips is in contact with the first bonding insulation layer of another one of the plurality of first semiconductor chips.

6. The semiconductor package of claim 1, wherein:
an upper surface of a first semiconductor chip positioned at the uppermost side among the plurality of first semiconductor chips is not covered by the molding material.

7. The semiconductor package of claim 6, wherein:
the upper surface of the first semiconductor chip positioned at the uppermost side among the plurality of first semiconductor chips is coplanar with the upper surface of the molding material.

8. The semiconductor package of claim 6, wherein:
a thickness of the first semiconductor chip positioned at the uppermost side among the plurality of first semiconductor chips is thicker than a thickness of the remaining first semiconductor chips.

9. The semiconductor package of claim 1,
further comprising a third semiconductor chip positioned on the plurality of first semiconductor chips,
wherein the molding material further surrounds a side surface of the third semiconductor chip, and
wherein the moisture permeation prevention film extends between the plurality of first semiconductor chips and the third semiconductor chip.

10. The semiconductor package of claim 9, wherein:
the third semiconductor chip is a dummy chip.

11. The semiconductor package of claim 10, wherein:
the dummy chip comprises at least one of a silicon substrate, a glass substrate, and a metal plate.

12. The semiconductor package of claim 9, wherein:
a thickness of the third semiconductor chip is thicker than a thickness of each of the plurality of first semiconductor chips.

13. The semiconductor package of claim 1, wherein:
the moisture permeation prevention film comprises at least one of silicon nitride (SixNy), silicon oxynitride (SiON), carbon-containing silicon oxide (SiOC), titanium dioxide (TiO2), aluminum oxide (Al2O3), tin oxide (SnOx), polyethylene terephthalate (PET), polypropylene (PP), polyethylene (PE), and polymethyl methacrylate (PMMA).

14. The semiconductor package of claim 1, wherein:
a thickness of the moisture permeation prevention film in a direction perpendicular to the side surface of the first semiconductor chips is 5 μm or less.

15. A semiconductor package comprising:
a first semiconductor chip including a first bonding pad, a first through via, and a second bonding pad electrically connected to the first through via;
a plurality of second semiconductor chips stacked on the first semiconductor chip and each including a third bonding pad, a second through via, and a fourth bonding pad electrically connected to the second through via;
a molding material positioned on the first semiconductor chip and surrounding side surfaces of the plurality of second semiconductor chips; and
a moisture permeation prevention film continuously positioned between an upper surface of the first semiconductor chip and the molding material, and between the side surfaces of each of the plurality of second semiconductor chips and the molding material,
wherein a third bonding pad of a second semiconductor chip positioned at the lowermost side of the plurality of second semiconductor chips is in contact with the second bonding pad,
wherein a fourth bonding pad of one of the plurality of second semiconductor chips is in contact with the third bonding pad of another one of the plurality of second semiconductor chips, and
wherein a thickness of the moisture permeation prevention film in a direction perpendicular to the upper surface of the first semiconductor chip between the upper surface of the first semiconductor chip and the molding material and a thickness of the moisture permeation prevention film in a direction perpendicular to the side surface of the second semiconductor chips between the side surfaces of each of the plurality of second semiconductor chips and the molding material is 5 μm or less, respectively.

16. The semiconductor package of claim 15, wherein:
the first semiconductor chip is a logic chip,
the plurality of second semiconductor chips are memory chips.

17. A semiconductor package manufacturing method comprising:
placing a first semiconductor wafer on a carrier substrate;
bonding a plurality of second semiconductor chips including a first bonding pad and a second bonding pad positioned at opposite surfaces from each other on the first semiconductor wafer;
forming a moisture permeation prevention film on an exposed upper surface of the first semiconductor wafer, a side of the plurality of the second semiconductor chips, and an upper surface of the second semiconductor chip positioned at an uppermost side among the plurality of second semiconductor chips;
molding the plurality of second semiconductor chips and the moisture permeation prevention film with a molding material;
removing the carrier substrate; and
dicing the first semiconductor wafer and separating the first semiconductor wafer into first semiconductor chips,
wherein, in the bonding the plurality of second semiconductor chips, the second bonding pad of one of the plurality of second semiconductor chips is in contact with the first bonding pad of another one of the plurality of second semiconductor chips.

18. The semiconductor package manufacturing method of claim 17, wherein:
in the forming the moisture permeation prevention film, the moisture permeation prevention film is formed by chemical vapor deposition (CVD), spray coating, or spin coating.

19. The semiconductor package manufacturing method of claim 17, wherein:
further comprising grinding the molding material and the moisture permeation prevention film to expose an upper surface of the second semiconductor chip positioned at the uppermost side of the plurality of second semiconductor chips.

20. The semiconductor package manufacturing method of claim 17,
further comprising
disposing a third semiconductor chip on the plurality of second semiconductor chips and the moisture permeation prevention film; and
grinding the molding material to expose an upper surface of the third semiconductor chip,
wherein, in the molding with molding material, the third semiconductor chip is molded with the molding material together with the plurality of second semiconductor chips and the moisture permeation prevention film.
